(19) United States
(12) Patent Application Publication
(10) Pub. No.: US 2024/0380176 A1
(43) Pub. Date: Nov. 14, 2024

(54) OPTICAL SEMICONDUCTOR ELEMENT, OPTICAL INTEGRATED ELEMENT, AND METHOD FOR MANUFACTURING OPTICAL SEMICONDUCTOR ELEMENT

(71) Applicant: FURUKAWA ELECTRIC CO., LTD., Tokyo (JP)

(72) Inventors: Masahiro YOSHIDA, Tokyo (JP); Kazuaki KIYOTA, Tokyo (JP)

(73) Assignee: FURUKAWA ELECTRIC CO., LTD., Tokyo (JP)

(21) Appl. No.: 18/782,562

(22) Filed: Jul. 24, 2024

Related U.S. Application Data
(63) Continuation of application No. PCT/JP2023/001804, filed on Jan. 20, 2023.

(30) Foreign Application Priority Data
Jan. 28, 2022 (JP) 2022-011609

(51) Int. Cl. H01S 5/10; H01S 5/22; H01S 5/227

(52) U.S. Cl. CPC H01S 5/101; H01S 5/22; H01S 5/2205; H01S 5/2275

(57) ABSTRACT

An optical semiconductor element includes: a substrate expanding while intersecting a first direction; a first protrusion part protruding from the substrate in the first direction and including semiconductor layers including an active layer; a second protrusion part protruding from the substrate in the first direction, in a position apart from the first protrusion part in a second direction intersecting the first direction, the second protrusion part including a semiconductor layer, and being configured to function as a position determining part used for determining a position relative to a component part different from the optical semiconductor element; and a first semiconductor layer formed throughout a first section positioned behind the first protrusion part in the first direction, a second section positioned behind the second protrusion part in the first direction, and a third section positioned between the first section and the second section.

This application is a continuation of International Application No. PCT/JP2023/001804, filed on Jan. 20, 2023 which claims the benefit of priority of the prior Japanese Patent Application No. 2022-011609, filed on Jan. 28, 2022, the entire contents of which are incorporated herein by reference.

### BACKGROUND

The present disclosure relates generally to an optical semiconductor element, an optical integrated element, and a method for manufacturing an optical semiconductor element. A known optical integrated element integrally includes: an optical semiconductor element such as a semiconductor laser element or a semiconductor optical amplifier and a section (hereinafter, “optical functional element”) having a waveguide (see Japanese Patent Application Laid-open No. 2017-92262).

### SUMMARY

For optical integrated elements of the type described above, it will be useful, for example, to be able to guarantee, more easily or with higher certainty, the precision level of a positional alignment between the optical semiconductor element and another component part different from the optical semiconductor element such as the optical functional element.

Three is a need for an optical semiconductor element, an optical integrated element, and a method for manufacturing an optical semiconductor element that are novel and improved, so as to make it possible to guarantee, more easily or with higher certainty, the precision level of the positional alignment between the optical semiconductor element and another component part different from the optical semiconductor element.

According to one aspect of the present disclosure, there is provided an optical semiconductor element including: a substrate expanding while intersecting a first direction; a first protrusion part protruding from the substrate in the first direction and including semiconductor layers including an active layer; a second protrusion part protruding from the substrate in the first direction, in a position apart from the first protrusion part in a second direction intersecting the first direction, the second protrusion part including a semiconductor layer, and being configured to function as a position determining part used for determining a position relative to a component part different from the optical semiconductor element; and a first semiconductor layer formed throughout a first section positioned behind the first protrusion part in the first direction, a second section positioned behind the second protrusion part in the first direction, and a third section positioned between the first section and the second section, the first semiconductor layer either: not getting etched by a prescribed etching agent capable of etching another semiconductor layer; or having a sufficiently small ratio between an etching rate thereof and an etching rate of said another semiconductor layer.

According to another aspect of the present disclosure, there is provided a method for manufacturing an optical semiconductor element, including: forming, over a substrate, a layered structure in which a plurality of semiconductor layers are layered in a first direction, while the plurality of semiconductor layers include a first semiconductor layer that either does not get etched by prescribed etching liquid or etching gas capable of etching another semiconductor layer or that has a sufficiently small ratio between an etching rate thereof and an etching rate of said another semiconductor layer; forming a plurality of mesas protruding from the substrate in a plurality of locations apart from each other in a second direction intersecting the first direction, by partially removing the layered structure on an opposite side from the substrate; forming a current blocking layer so as to fill a gap between the plurality of mesas; and forming a first protrusion part including a first mesa being one of the plurality of mesas and a section of the current blocking layer positioned adjacent to the first mesa and a second protrusion part including a second mesa being one of the plurality of mesas and different from the first mesa, by performing an etching process while using the etching liquid or the etching gas which uses the first semiconductor layer as an etching stop layer.

### BRIEF DESCRIPTION OF THE DRAWINGS

FIG. 1 is an illustrative and schematic plan view of an optical semiconductor element according to a first embodiment;

FIG. 2 is a cross-sectional view taken at II-II in FIG. 1;

FIG. 3 is an illustrative and schematic side view of an optical integrated element according to the first embodiment;

FIG. 4 is an illustrative and schematic cross-sectional view of a workpiece in progress during manufacturing steps of the optical semiconductor element according to the first embodiment;

FIG. 5 is an illustrative and schematic cross-sectional view of a workpiece in progress at a stage later than in FIG. 4, during the manufacturing steps of the optical semiconductor element according to the first embodiment;

FIG. 6 is an illustrative and schematic cross-sectional view of a workpiece in progress at the same stage as in FIG. 5, during manufacturing steps of an optical semiconductor element according to a reference example;

FIG. 7 is an illustrative and schematic plan view of an optical semiconductor element according to a second embodiment;

FIG. 8 is an illustrative and schematic plan view of an optical semiconductor element according to a third embodiment; and

FIG. 9 is an illustrative and schematic plan view of an optical semiconductor element according to a fourth embodiment.

### DETAILED DESCRIPTION

The following will describe exemplary embodiments of the present disclosure. The configurations of the embodiments described below and the effects and the results (the advantageous effects) brought about by the configurations are merely examples. It is possible to realize the present disclosure by using other configurations besides those disclosed in the following embodiments. Further, with the present disclosure, it is possible to achieve at least one of various types of advantageous effects (which include derivative advantageous effects) realized by the configurations.

The plurality of embodiments described below include certain configurations that are the same as each other. Thus, by using the configurations of the embodiments, it is possible to achieve the same effects and advantageous effects based on the same configurations. Further, in the following explanations, some of the configurations that are the same will be referred to by using the same reference characters, and duplicate explanations thereof may be omitted.

In the present disclosure, the ordinal numbers are assigned for the sake of convenience, in order to distinguish directions, sections, and the like and are not intended to indicate priority ranking or sequential order.

In the drawings, the arrow X indicates an X direction; the arrow Y indicates a Y direction; and the arrow Z indicates a Z direction. The X direction, the Y direction, and the Z direction intersect one another and are orthogonal to one another. Further, in the following sections, the X direction may be referred to as a longitudinal direction or an extending direction; the Y direction may be referred to as a latitudinal direction or a width direction; and the Z direction may be referred to as a layered direction or a height direction.

Further, the drawings are schematically drawn for the purpose of explanation. Thus, the scales and the proportions in the drawings may not necessarily match those in reality.

### First Embodiment

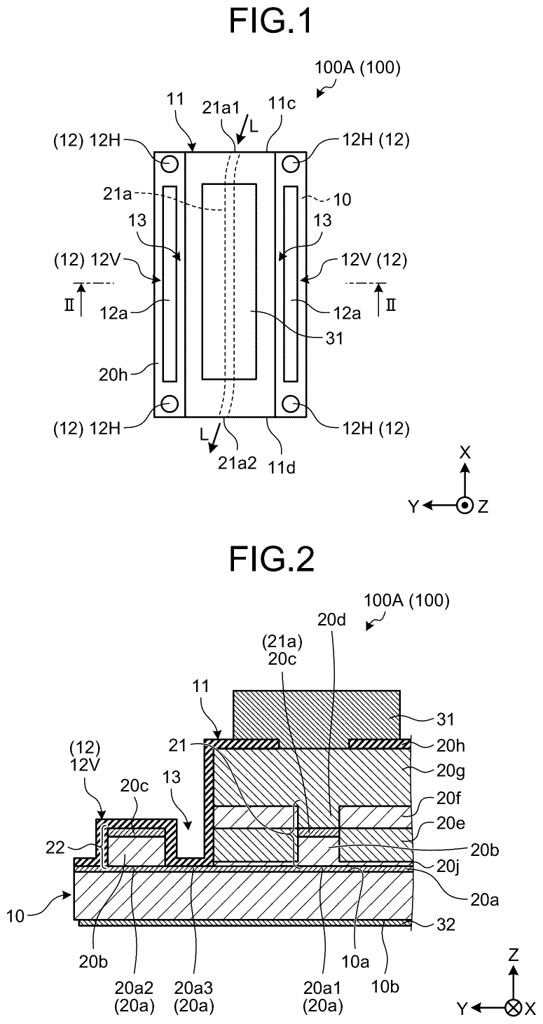

FIG. 1 is a plan view of an optical semiconductor element 100A (100) according to a first embodiment. FIG. 2 is a cross-sectional view taken at II-II in FIG. 1. The optical semiconductor element 100A is structured as a publicly-known semiconductor optical amplifier.

As illustrated in FIGS. 1 and 2, the optical semiconductor element 100A includes a substrate 10, a protrusion part 11, and protrusion parts 12 (12V, 12H).

The protrusion parts 11 and 12 protrude from the substrate 10 in the Z direction. Further, the protrusion part 11 is positioned apart from each of the protrusion parts 12 in the Y direction. The protrusion part 11 is an example of the first protrusion part. The protrusion parts 12 are examples of the second protrusion part. Further, the Z direction is an example of the first direction. The Y direction is an example of the second direction.

The protrusion part 11 is a section that functions as an optical semiconductor amplifier, for example, and may be referred to as a functional part.

As illustrated in FIG. 1, the protrusion part 11 extends along the X direction. The protrusion part 11 includes, on the inside thereof, an active layer 21a serving as an optical waveguide. The active layer 21a extends substantially along the X direction. It should be noted, however, that the active layer 21a is at an angle with respect to the X direction and the Y direction, in the vicinity of an end part 21al in the X direction and an end part 21a2 in the direction opposite to the X direction. This configuration prevents light reflected by the end parts 21al and 21a2 from returning to a waveguide path. The protrusion part 11 has a buried waveguide structure (a Buried Heterostructure (BH) waveguide structure).

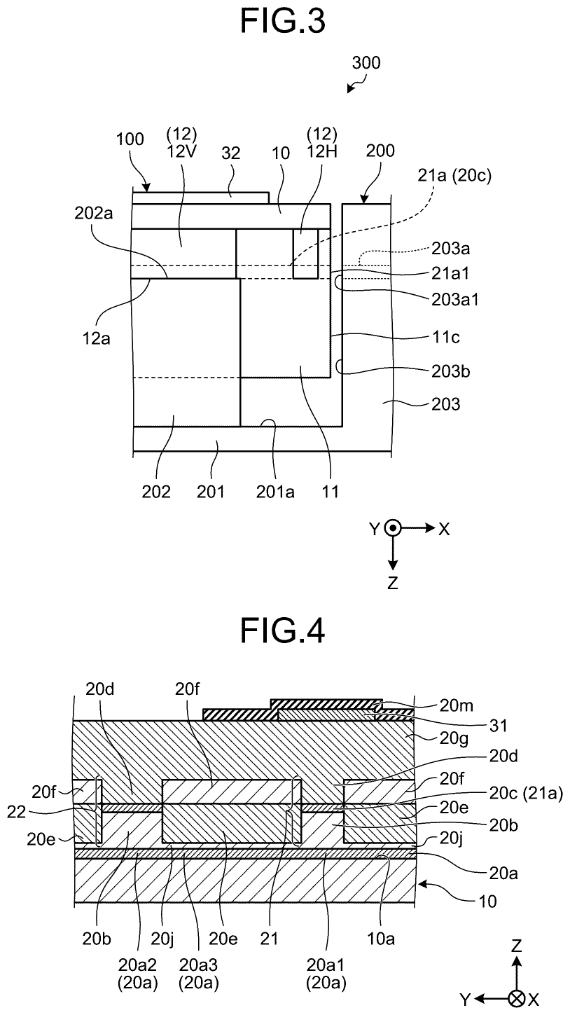

The optical semiconductor element 100A includes, as the protrusion parts 12, two protrusion parts 12V and four protrusion parts 12H. The protrusion parts 12 are sections used for determining a position relative to a component part (hereinafter, “another component part”) different from the optical semiconductor element 100, such as an optical functional element 200 (see FIG. 3), and thus may be referred to as position determining parts.

As illustrated in FIG. 1, the two protrusion parts 12V are each positioned at an interval, in the Y direction, from the protrusion part 11 to the front and to the rear of the protrusion part 11. The protrusion parts 12V extend in the X direction while having a substantially constant width in the Y direction and a substantially constant height in the Z direction. The protrusion parts 12V are used, for example, for determining the positions of the optical semiconductor element 100A and the optical functional element 200 relative to each other in terms of the Z direction. The position determination realized by the protrusion parts 12V is, for example, a position determination based on contact between the optical semiconductor element 100A and the optical functional element 200. In this situation, end parts 12a of the protrusion parts 12V in the Z direction are each a plane facing the Z direction and intersecting the Z direction. The end parts 12a may be referred to as facets or contact faces. Further, when the optical semiconductor element 100A is supported by another component part via the protrusion parts 12V, it is desirable, from a viewpoint of stability of the support, to configure the length of each of the protrusion parts 12V in the X direction to be equal to or longer than one-third of the lengths of the optical semiconductor element 100 and the protrusion part 11 in the X direction.

Further, the four protrusion parts 12H are provided in the vicinity of an end part of the optical semiconductor element 100A in the X direction and another end part thereof in the direction opposite to the X direction. Among the four protrusion parts 12H, the two protrusion parts 12H positioned at the end part in the X direction are each positioned at an interval from the protrusion part 11 to the front and to the rear of the protrusion part 11 in the Y direction. Further, among the four protrusion parts 12H, the other two protrusion parts 12H positioned at the other end part in the direction opposite to the X direction are also each positioned at an interval from the protrusion part 11 to the front and to the rear of the protrusion part 11 in the Y direction. The protrusion parts 12H are used for determining the positions of the optical semiconductor element 100A and the optical functional element 200 relative to each other in terms of the X direction and the Y direction, i.e., for determining the positions in terms of the directions intersecting the Z direction. More specifically, the position determination in the X direction and the Y direction realized by the protrusion parts 12H is, for example, a position determination based on an image recognition or an image analysis performed on an image taken of the protrusion parts 12H by a camera.

However, the shapes, the quantities, the positional arrangements, and the like of the protrusion parts 12V and 12H are not limited to those in the example of FIG. 1. One each of the protrusion parts 12V and 12H may be provided. It is also acceptable to provide a protrusion part in which a protrusion part 12H and a protrusion part 12V are integrally formed.

The substrate 10 has a substantially constant thickness in the Z direction, while expanding so as to intersect the Z direction. As illustrated in FIG. 2, the substrate 10 has a face 10a and a face 10b. The face 10a is facing the Z direction and intersects the Z direction. Further, the face 10b is positioned on the opposite side from the face 10a, is facing the direction opposite to the Z direction, and intersects the Z direction. The substrate 10 is structured with n-InP, for example.

The protrusion parts 11 includes a mesa 21. The protrusion parts 12 include mesas 22. The mesa 21 is an example of the first mesa. The mesas 22 are examples of the second mesa.

The mesa 21 and the mesas 22 are manufactured through mutually the same semiconductor process. For this reason, the mesa 21 and the mesas 22 both include a plurality of mutually-same semiconductor layers (a first layer 20a, a second layer 20b, and a third layer 20c) that are layered and thus have layered structures that are partially the same as each other. In other words, mutually the same semiconductor layers included in the mesas 21 and 22 are manufactured by using the same ingredients, while being aligned in the Y direction and being in mutually the same position, in terms of the Z direction, from the face 10a of the substrate 10. However, because the end parts, in the Z direction, of the mesas 22 are removed by an etching process, the end part, in the Z direction, of the mesa 21 includes a semiconductor layer (a fourth layer 20d) that is not included in the mesas 22.

For example, the first layer 20a is structured with n-InGaAsP. The first layer 20a is a so-called quaternary layer and has a characteristic where the layer either does not get etched by a prescribed etching agent such as etching liquid (e.g., hydrochloric acid) or etching gas capable of etching another semiconductor layer (e.g., a cladding layer structured with InP) or has a sufficiently small (e.g., 1/10 or smaller) ratio between an etching rate thereof and an etching rate of the other semiconductor layer. The first layer 20a functions as an etching stop layer at the time of forming recessed parts 13 through an etching process. The thickness of the first layer 20a may be approximately 20 [nm], for example. The first layer 20a is an example of the first semiconductor layer. The recessed parts 13 are examples of the first recessed part.

The first layer 20a is formed so as to widely expands over the face 10a of the substrate 10, for example, so as to cover substantially the entirety of the face 10a and includes: a section 20al positioned behind the protrusion part 11 in the Z direction; a section 20a2 positioned behind each of the protrusion parts 12V (12) in the Z direction; and a section 20a3 positioned behind, in the Z direction, each of the recessed parts 13 that are each positioned between the protrusion part 11 and a different one of the protrusion parts 12. Further, although not illustrated in FIG. 2, the first layer 20a also includes: a section positioned behind each of the protrusion parts 12H in the Z direction; a section positioned behind, in the z direction, each of the recessed parts 13 that are each positioned between the protrusion part 11 and a different one of the protrusion parts 12H; a section positioned behind, in the Z direction, each of the recessed parts 13 that are each positioned between a protrusion part 12V and a protrusion part 12H; and, when the plurality of protrusion parts 11 are provided, a section positioned behind, in the Z direction, a recessed part 14 (see FIG. 8) positioned between the plurality of protrusion parts 11. These sections and the sections 20a1, 20a2, and 20a3 are formed to be contiguous without any gaps therebetween. Consequently, it can be said that the protrusion parts 11 and 12 (12V and 12H) protrude from the first layer 20a in the Z direction. The section 20al is an example of the first section. The section 20a2 is an example of the second section. The section 20a3 is an example of the third section.

The second layer 20b is structured with n-InP, for example and, in the mesa 21, functions as a cladding layer.

The third layer 20c has, for example, a layered structure containing n-InGaAsP and is a so-called quaternary layer. The third layer 20c included in the mesa 21 functions as the active layer 21a. In order to function as the active layer 21a, the third layer 20c has a composition that appropriately functions with respect to light in a wavelength band of 1.55 [μm], for example.

In contrast, the third layer 20c included in the mesas 22 functions as an etching stop layer (a mask) at the time of forming the mesas 22 through an etching process and at the time of forming the recessed parts 13 through an etching process. The third layer 20c included in the mesas 22 has the same composition as that of the active layer 21a and is aligned with the active layer 21a in the Y direction. The third layer 20c is an example of the second semiconductor layer. In addition, the mesas 22 may include another second semiconductor layer that functions as an etching stop layer (a mask), separately from the third layer 20c.

The mesas 22 structure the protrusion parts 12. In the mesas 22, the protrusion parts 12 are each covered by an insulation layer 20h, but do not necessarily need to be.

Further, as semiconductor layers that are not included in the protrusion parts 12 (the mesas 22), the protrusion part 11 includes a fourth layer 20d, current blocking layers 20e and 20f, and a cladding layer 20g.

The fourth layer 20d is structured with p-InP, for example, and, in the mesa 21, functions as a cladding layer.

In the protrusion part 11, the mesa 21 is surrounded by a fifth layer 20j and the current blocking layers 20e and 20f that are positioned adjacent thereto in the Y direction and the position opposite to the Y direction and by a cladding layer 20g positioned adjacent thereto in the Z direction. The fifth layer 20j is structured by using the same materials as that of the second layer 20b. The current blocking layer 20e is structured with p-InP, for example. The current blocking layer 20f is structured with n-InP, for example. Further, the cladding layer 20g is structured with p-InP, for example.

On the opposite side from the substrate 10 relative to the cladding layer 20g, an electrode 31 is provided. The electrode 31 is a P-side electrode and is positioned apart from the active layer 21a in the Z direction. For example, the electrode 31 has a layered structure including, for example, a contact layer, a base layer, a barrier layer, a thick film layer, and/or the like (not illustrated).

The facets (lateral faces) of the protrusion parts 11 and 12 in the Y direction and the direction opposite to the Y direction and the facets (top faces) in the Z direction are covered by the insulation layer 20h, except for an opening part through which the electrode 31 extends, over the protrusion part 11. The insulation layer 20h is structured with SiN, for example.

An electrode 32 is provided over the face 10b of the substrate 10. The electrode 32 is an N-side electrode and has a layered structure containing, for example, AuGe, Ni, and Au.

### Structures of the Optical Functional Element and the Optical Integrated Element

FIG. 3 is a side view of a part of an optical integrated element 300 including the optical semiconductor element 100 and the optical functional element 200. FIG. 3 illustrates a state in which the optical semiconductor element 100 and the optical functional element 200 have been positionally aligned with each other. As illustrated in FIG. 3, in the optical integrated element 300, the optical semiconductor element 100 and the optical functional element 200 are positioned on top of each other in the Z direction. The optical functional element 200 may be referred to as a silicon platform.

The optical functional element 200 includes a base 201, a protrusion part 202, and a body 203. The protrusion part 202 protrudes from a face 201a of the base 201 in the direction opposite to the Z direction. The body 203 also protrudes from the face 201a in the direction opposite to the Z direction. Inside the body 203, an optical waveguide including a core 203a extending in the X direction is provided. In the optical integrated element 300, in the state where the optical semiconductor element 100 and the optical functional element 200 have been positionally aligned with each other as illustrated in FIG. 3, a facet 203b of the body 203 in the direction opposite to the X direction is facing the facet 11c of the optical semiconductor element 100 in the X direction, while the end part 21al of the active layer 21a and an end part 203al of the core 203a are facing the X direction and are aligned with each other in the X direction. With this configuration, the end part 21al and the end part 203al are optically coupled. The X direction is an example of the third direction.

As explained above, in the present embodiment, the mesa 21 included in the protrusion part 11 and the mesas 22 included in the protrusion parts 12V have the layered structures in the Z direction that are partially the same as each other. Accordingly, by setting the height of the protrusion parts 12V in the Z direction, i.e., the positions of the end parts 12a in the Z direction, with respect to the third layer 20c in the protrusion parts 12V, it is possible to set the height of the protrusion parts 12V in the Z direction, i.e., the positions of the end parts 12a in the Z direction, with respect to the active layer 21a in the mesa 21 inside the protrusion part 11. Consequently, according to the present embodiment, it is possible to positionally align, in the Z direction, the active layer 21a of the optical semiconductor element 100 with the core 203a of the optical functional element 200, more easily or with a higher level of precision. Thus, an advantageous effect is achieved where it is possible to prevent degradation of optical coupling efficiency between the active layer 21a and the core 203a, more easily or with higher certainty.

Further, in the present embodiment, the optical semiconductor element 100 includes the plurality of protrusion parts 12V. In addition, the protrusion part 11 is positioned between the plurality of protrusion parts 12V. With this configuration, an advantageous effect is achieved where it is possible to more stably have the optical semiconductor element 100 supported by the plurality of protrusion parts 12V.

### A Method for Manufacturing the Optical Semiconductor Element

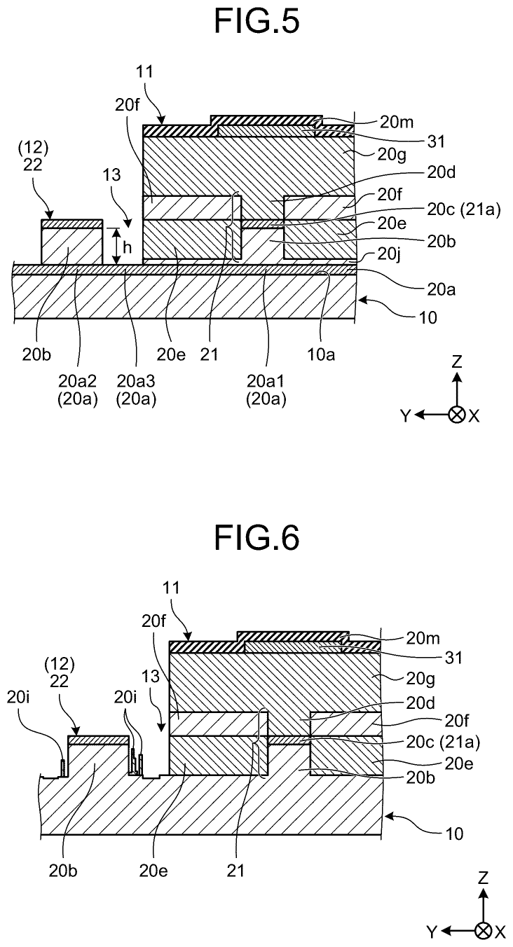

FIGS. 4 and 5 are drawings illustrating a workpiece in progress during manufacturing steps in a method for manufacturing the optical semiconductor element 100.

To begin with, as illustrated in FIG. 4, on the substrate 10 serving as a wafer, the first layer 20a, the second layer 20b, the third layer 20c, and the fourth layer 20d are layered by crystal growth.

Subsequently, through an etching process (a first etching process) using prescribed etching liquid or etching gas together with a mask, certain sections of the workpiece in FIG. 4 positioned on the opposite side from the substrate 10 are selectively and partially removed, and the mesa 21 and the mesas 22 are formed at intervals in the Y direction. In the surroundings of the mesa 21 and the mesas 22, trenches (not illustrated) are formed. In this situation, the first etching process to form the mesas 21 and 22 is performed so that the fifth layer 20j remains on the first layer 20a.

After that, the current blocking layers 20e and 20f are formed so that the trenches are wholly buried. In this situation, the mask used in the first etching process is removed.

Subsequently, the cladding layer 20g, an insulation layer 20m, and at least a part of the electrode 31 are formed, on the opposite side from the substrate 10, on the workpiece having the current blocking layers 20e and 20f formed thereon. As a result, the workpiece illustrated in FIG. 4 is obtained.

After that, certain sections of the workpiece in FIG. 4 that are positioned on the opposite side from the substrate 10 and positioned between the mesa 21 and the mesas 22 are removed through an etching process (a second etching process) using prescribed etching liquid or etching gas, while using the insulation layer 20m and the third layer 20c in the mesas 22 as etching masks (etching stop layers), so as to form, as illustrated in FIG. 5, the protrusion part 11 including the mesa 21 and the mesas 22 (parts of the protrusion parts 12V). As a result of the etching process, the protrusion part 11 including the mesa 21 on the inside thereof and the recessed parts 13 between the protrusion part 11 and the mesas 22 are formed. In addition, in the recessed parts 13, the first layer 20a functions as an etching stop layer.

Further, after the insulation layer 20m is removed, an insulation layer 20h such as that illustrated in FIG. 2 is formed. The insulation layer 20h is partially removed over the electrode 31 so as to form an opening. Further, by adding, to the electrode 31, a conductor that goes through the opening and extends to a position above the insulation layer 20h, the electrode 31 illustrated in FIG. 2 is formed. In addition, after the face 10b is formed by polishing the facet of the substrate 10 in the direction opposite to the Z direction, the electrode 32 is formed on the face 10b by performing a vapor deposition liftoff process, for example. Subsequently, heat treatment is performed to establish an ohmic connection among the electrode 31, the electrode 32, and the semiconductor layers in the protrusion part 11. In addition, the lateral faces of the protrusion part 11 are covered by the insulation layer 20h.

The wafer (not illustrated) to which the abovementioned processes have been performed is cleaved, and a low-reflection coating is applied to the facet 11c in the X direction and a facet 11d in the direction opposite to the X direction (see FIG. 1). The optical semiconductor element 100 illustrated in FIGS. 1 and 2 is thus completed.

The inventors conducted intensive studies on the configuration and the processes described above and discovered that, if the first layer 20a were not provided, there would be a possibility that the recessed parts 13 might have an etching residue such as projections 20i illustrated in FIG. 6 (a reference example), for instance, at the time of the etching process to obtain the workpiece in FIG. 5 from the workpiece in FIG. 4. We learned that the etching residue brings about inconveniences as follows, for example: (1) Due to the projections 20i being taller than the end parts 12a, the process of determining the position of the optical semiconductor element 100 in the Z direction using the protrusion parts 12V would be hindered; (2) In a planar view taken in the direction opposite to the Z direction, the shape of the boundaries of the protrusion parts 12H would be changed from a prescribed shape, which would hinder image recognition or an image analysis of the protrusion parts 12H, and as a result, the process of determining the position of the optical semiconductor element 100 in the X direction or the Y direction would be hindered; and (3) Because the residue in bottom parts of the recessed parts 13 would work as a path for a leakage current from the protrusion part 11, it would be impossible to apply an electric current of a required magnitude from the electrodes 31 and 32 to the active layer 21a in the mesa 21.

To cope with the circumstances described above, the inventors conceived of the configuration in which the first layer 20a that functions as an etching stop layer is provided behind the recessed parts 13 in the Z direction. With this configuration, it is possible to perform the etching process until the first layer 20a is exposed in the recessed parts 13, and the etching residue such as the projections 20i disappear from the recessed parts 13. As a result, it is possible to avoid occurrences of the inconveniences (1) to (3) described above. In addition, because it is possible to manage the etching process more easily, another advantageous effect is also achieved where it is possible to prevent the mechanical strength from being degraded by excessive shaving of the lateral faces of the protrusion part 11 and the mesas 22 which might be caused by the etching process. Furthermore, it is possible to form the first layer 20a relatively easily throughout substantially the entirety of the face 10a of the substrate 10. Thus, it is considered that disadvantages to configurations without the first layer 20a such as that illustrated in FIG. 6 are extremely small.

In addition, the inventors conducted intensive studies and learned that, with the configuration according to the present embodiment, an advantageous effect is achieved where it is possible to optically isolate the active layer 21a from the first layer 20a, i.e., it is possible to suppress an optical absorption at the first layer 20a of the light propagating through the active layer 21a, to be lower than a level under which certain expected characteristics are not to be impacted, by ensuring that a distance h between the active layer 21a and the first layer 20a in the Z direction, i.e., the distance h between the third layer 20c and the first layer 20a, is equal to or longer the 2 [μm]. In addition, from a viewpoint of preventing leakage currents, it is necessary to completely remove at least the current blocking layer 20e (the p-InP layer). Thus, for this reason also, we learned that it is desirable to ensure that the distance h is equal to or longer than 2 [μm]. In this situation, the distance h by which the active layer 21a can optically be isolated from the first layer 20a is, for example, 2 [μm] for the configuration of the present embodiment; however, the value of the distance h may vary according to specifications of the semiconductor layers or the like.

As explained above, according to the structure and the method of the present embodiment, it is possible to form the protrusion parts 12 with a higher level of precision and to also inhibit the leakage currents from the protrusion part 11. In other words, according to the present embodiment, it is possible to provide the optical semiconductor element 100, the optical integrated element 300, and the method for manufacturing the optical semiconductor element 100 that are improved and novel.

Further, in the optical semiconductor element 100 of the present embodiment, the protrusion parts 12 also contribute to enhancing rigidity and strength of the optical semiconductor element 100. From this viewpoint, it is desirable to configure the optical semiconductor element 100 so as to include a plurality of protrusion parts 12 and to include the protrusion parts 12 that are elongated like the protrusion parts 12V. When such protrusion parts 12 are used, the optical semiconductor element 100 does not get deformed easily, and it is therefore possible to prevent optical coupling loss with other component parts from being increased by such deformation.

Further, in the optical integrated element 300 according to the present embodiment, the height of the protrusion parts 12 from the recessed parts 13 is lower than the height of the protrusion part 11 from the recessed parts 13, so that the end parts 12a of the protrusion parts 12 of the optical semiconductor element 100 are in contact with end parts 202a of the protrusion part 202 of the optical functional element 200. In that situation, if a positional alignment were to be achieved by bringing the protrusion parts of a first one of the optical semiconductor element 100 and the optical functional element 200 to be in contact with the recessed parts of a second one the two, it would be necessary to provide the second one of the two with a surrounding wall to form the recessed parts that house therein the protrusion parts provided in the first one of the two. As a result, there would be a possibility that, in a section involved in the positional alignment, the structure of the second one of the two would be larger in the direction intersecting the protrusion direction (the layered direction), because the protrusion parts overlap with the surrounding wall in the direction intersecting the protrusion direction. In contrast, the optical integrated element 300 according to the present embodiment is configured so that the protrusion parts 12 come into contact with the protrusion part 202, the structure is kept more compact, in comparison to the structure in which the protrusion parts are positionally aligned with the recessed parts. The protrusion part 202 may be referred to as a third protrusion part. The end parts 202a are examples of the contact part.

### Second Embodiment

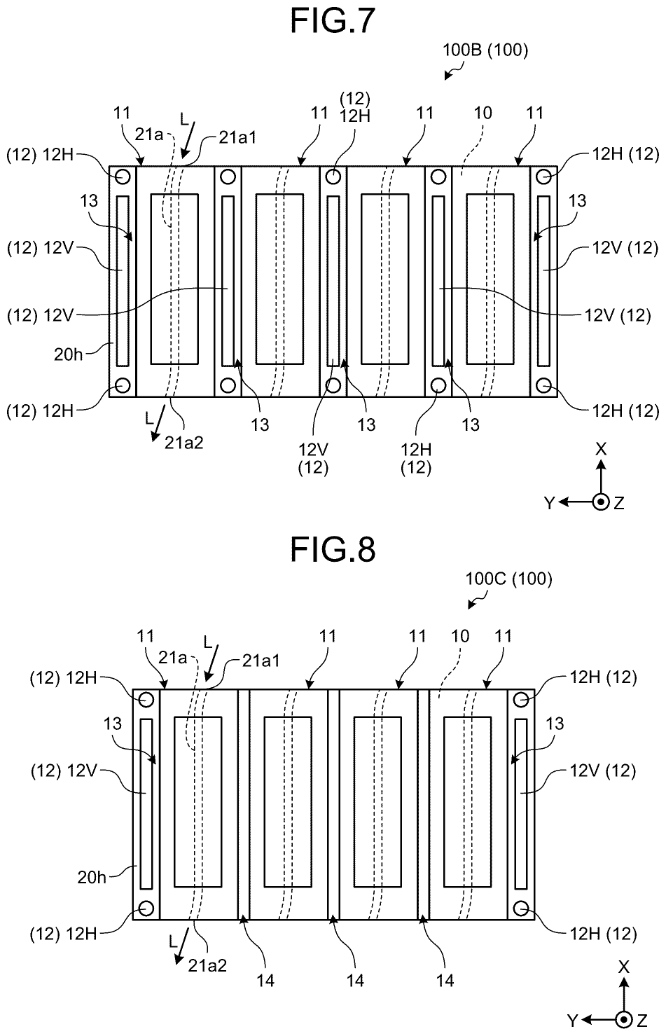

FIG. 7 is a plan view of an optical semiconductor element 100B according to a second embodiment. In the optical semiconductor element 100B according to the present embodiment, a plurality of protrusion parts 11 each having the same configuration as that in the first embodiment are arranged in the Y direction so as to structure bars (an array). By any two of the protrusion parts 11 positioned adjacent to each other in the Y direction, a protrusion part 12 positioned between the two protrusion parts 11 is shared.

The optical semiconductor element 100B according to the present embodiment has a configuration similar to that of the optical semiconductor element 100A according to the first embodiment. Thus, the present embodiment is also able to achieve the same or similar advantageous effects as those achieved by the first embodiment. Further, the configuration having the plurality of protrusion parts 11 (the active layer 21a) like in the present embodiment is suitable for use in an optical element such as an optical matrix switch, for example, that includes a plurality of semiconductor optical amplifiers.

### Third Embodiment

FIG. 8 is a plan view of an optical semiconductor element 100C according to a third embodiment. The optical semiconductor element 100C according to the present embodiment also has a configuration in which a plurality of protrusion parts 11 each having the same configuration as that in the first embodiment are arranged in the Y direction so as to structure bars (an array) and has a configuration similar to that of the optical semiconductor element 100B according to the second embodiment. In the present embodiment, however, it should be noted that the protrusion parts 12 are not provided between any of the two protrusion parts 11 positioned adjacent to each other in the Y direction. Instead, the protrusion parts 12 for the position determining purpose are provided only in the end part in the Y direction and in the end part in the direction opposite to the Y direction of the optical semiconductor element 100C. Provided between any two of the protrusion parts 11 positioned adjacent to each other in the Y direction is a recessed part 14 having a substantially equal depth to that of the recessed parts 13. The recessed part 14 is an example of the second recessed part.

The optical semiconductor element 100C according to the present embodiment also has a configuration similar to that of the optical semiconductor element 100A according to the first embodiment. Thus, the present embodiment is also able to achieve the same or similar advantageous effects as those achieved by the first embodiment. In addition, another advantageous effect is achieved where, between any two of the protrusion parts 11 positioned adjacent to each other in the Y direction, it is possible to prevent leakage currents that may occur via the recessed parts 14 and the sections positioned behind the recessed parts 14 in the Z direction.

### Fourth Embodiment

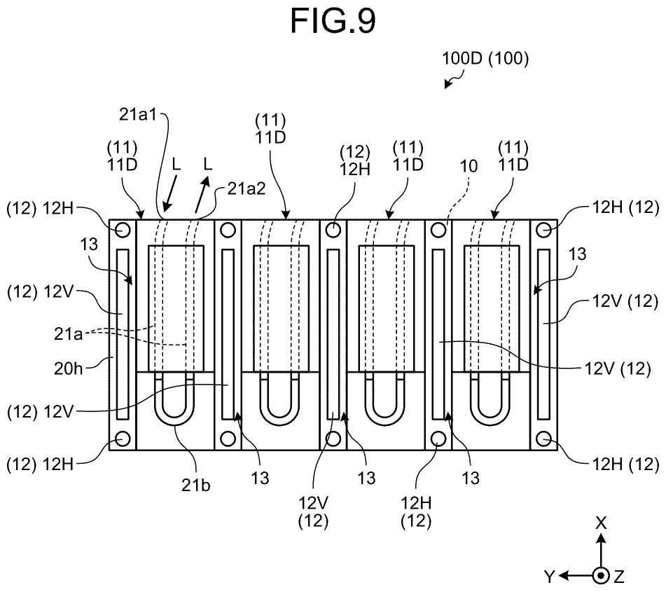

FIG. 9 is a plan view of an optical semiconductor element 100D according to a fourth embodiment. The optical semiconductor element 100D according to the present embodiment also has a configuration in which a plurality of protrusion parts 11D (11) are arranged in the Y direction so as to structure bars (an array). It should be noted, however, that the present embodiment is different from the other embodiments described above in that the optical semiconductor element 100D includes a plurality of waveguides that are each bent in a U-shape, in a planar view taken in the direction opposite to the Z direction. The waveguides are positioned apart from one another in the Y direction and include: two active layers 21a that each extend in the X direction at mutually the same height (position) in the Z direction; and passive parts 21b that are each curved in a U shape and that connect the end parts, in the direction opposite to the X direction, of the two active layers 21a to each other. Each of the passive parts 21b is a passive waveguide having a high mesa structure and is optically connected, by a butt joint connection, to the active layer 21a being a buried waveguide. Each of the protrusion parts 11D has formed therewith two end parts 21al and 21a2 of the waveguide, so that light L input to one of the end parts 21al is optically amplified via one of the active layers 21a, the passive part 21b, and the other active layer 21a and is output from the other end part 21a2.

The optical semiconductor element 100D according to the present embodiment also has a configuration similar to that of the optical semiconductor element 100A according to the first embodiment. Consequently, the present embodiment is also able to achieve the same or similar advantageous effects as those achieved by the first embodiment. In addition, because the optical semiconductor element 100D according to the present embodiment includes the U-shaped waveguides including the passive parts 21b, it is possible to set a gain length of the active layer 21a as appropriate, separately from the length of the optical semiconductor element 100D. Another advantageous effect is therefore achieved where the degree of freedom in designing the optical semiconductor element 100D is enhanced.

For example, the optical semiconductor element is also applicable to a laser light-emitting element such as a Distributed Feedback (DFB) semiconductor laser, for example.

According to the present disclosure, it is possible to provide the optical semiconductor element, the optical integrated element, and the method for manufacturing the optical semiconductor element that are novel and improved. Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical semiconductor element comprising:
a substrate expanding while intersecting a first direction;
a first protrusion part protruding from the substrate in the first direction and including semiconductor layers including an active layer;
a second protrusion part protruding from the substrate in the first direction, in a position apart from the first protrusion part in a second direction intersecting the first direction, the second protrusion part including a semiconductor layer, and being configured to function as a position determining part used for determining a position relative to a component part different from the optical semiconductor element; and
a first semiconductor layer formed throughout a first section positioned behind the first protrusion part in the first direction, a second section positioned behind the second protrusion part in the first direction, and a third section positioned between the first section and the second section, the first semiconductor layer either: not getting etched by a prescribed etching agent capable of etching another semiconductor layer; or having a sufficiently small ratio between an etching rate thereof and an etching rate of said another semiconductor layer.

2. The optical semiconductor element according to claim 1 wherein the active layer is positioned apart from the first semiconductor layer, by a distance in the first direction equal to or longer than a distance that enables optical isolation therebetween.

3. The optical semiconductor element according to claim 1, wherein a protrusion height, in the first direction, of the second protrusion part from a first recessed part positioned between the first protrusion part and the second protrusion part is shorter than a protrusion height, in the first direction, of the first protrusion part from the first recessed part.

4. The optical semiconductor element according to claim 1, wherein the second protrusion part includes, in a position apart from the first semiconductor layer in the first direction, a second semiconductor layer either: not getting etched by prescribed etching liquid or etching gas capable of etching another semiconductor layer; or having a sufficiently small ratio between an etching rate thereof and an etching rate of said another semiconductor layer.

5. The optical semiconductor element according to claim 4, wherein the second semiconductor layer has a same composition as that of the active layer and is aligned with the active layer in the second direction.

6. The optical semiconductor element according to claim 1, wherein
the first protrusion part includes a first mesa in which a plurality of semiconductor layers including the active layer are layered, and
the second protrusion part includes a second mesa having, at least partially, a same layered structure as the first mesa.

7. The optical semiconductor element according to claim 6, comprising a waveguide including the active layer and having a bent shape as viewed in a direction along the first direction.

8. The optical semiconductor element according to claim 7, wherein the waveguide is bent so as to have a U-shape as viewed in a direction along the first direction.

9. The optical semiconductor element according to claim 1, comprising a plurality of second protrusion parts as the second protrusion part.

10. The optical semiconductor element according to claim 9, wherein the first protrusion part is positioned between the plurality of second protrusion parts.

11. The optical semiconductor element according to claim 1, wherein the second protrusion part is used for determining the position relative to an optical functional element having an optical waveguide including a core.

12. The optical semiconductor element according to claim 11, wherein the second protrusion part is used for determining the position, in terms of the first direction, relative to the optical functional element.

13. The optical semiconductor element according to claim 11, wherein the second protrusion part is used for determining the position, in terms of a direction intersecting the first direction, relative to the optical functional element.

14. The optical semiconductor element according to claim 1, comprising a plurality of first protrusion parts as the first protrusion part.

15. The optical semiconductor element according to claim 14, wherein the second protrusion part is positioned between the plurality of first protrusion parts.

16. The optical semiconductor element according to claim 14, comprising a second recessed part provided between the plurality of first protrusion parts, the second recessed part being substantially as deep as the first recessed part positioned between the first protrusion part and the second protrusion part.

17. An optical integrated element comprising:
an optical functional element having an optical waveguide including a core; and
the optical semiconductor element according to claim 1, wherein
the optical functional element includes a contact part positioned on an opposite side from the substrate relative to the second protrusion part, the optical functional element being in contact with the second protrusion part, and
the core and the active layer are facing a third direction intersecting the first direction.

18. A method for manufacturing an optical semiconductor element, comprising:
forming, over a substrate, a layered structure in which a plurality of semiconductor layers are layered in a first direction, while the plurality of semiconductor layers include a first semiconductor layer that either does not get etched by prescribed etching liquid or etching gas capable of etching another semiconductor layer or that has a sufficiently small ratio between an etching rate thereof and an etching rate of said another semiconductor layer;
forming a plurality of mesas protruding from the substrate in a plurality of locations apart from each other in a second direction intersecting the first direction, by partially removing the layered structure on an opposite side from the substrate;
forming a current blocking layer so as to fill a gap between the plurality of mesas; and
forming a first protrusion part including a first mesa being one of the plurality of mesas and a section of the current blocking layer positioned adjacent to the first mesa and a second protrusion part including a second mesa being one of the plurality of mesas and different from the first mesa, by performing an etching process while using the etching liquid or the etching gas which uses the first semiconductor layer as an etching stop layer.
